(19) United States
(12) Patent Application Publication
(10) Pub. No.: US 2023/0055868 A1
(43) Pub. Date: Feb. 23, 2023

(54) METHOD FOR RESOLVING DEFECT OF SURFACE STRUCTURE OF TRENCH AND METHOD FOR PREPARING SEMICONDUCTOR STRUCTURE

(71) Applicant: CHANGXIN MEMORY TECHNOLOGIES, INC., Hefei City, Anhui (CN)

(72) Inventor: Tao CHEN, Hefei City, Anhuicn (CN)

(21) Appl. No.: 17/599,459

(22) PCT Filed: Jun. 8, 2021
(86) PCT No.: PCT/CN2021/098948

§ 371 Date: Sep. 28, 2021

(30) Foreign Application Priority Data
Jul. 16, 2020 (CN) 202010686770.1

(51) Int. Cl. H01L 21/02; H01L 27/108

(52) U.S. Cl. CPC H01L 21/02068; H01L 21/02063; H01L 27/10891

(57) ABSTRACT

The embodiments of the present disclosure propose a method for resolving a defect of surface structures of trenches and a method for preparing a semiconductor structure. The method for resolving a defect of surface structures of trenches includes: cleaning the trenches on a base with a cleaning liquid after the trenches are formed on the base, where the cleaning liquid is water.

### CROSS-REFERENCE TO RELATED APPLICATIONS

The present disclosure claims the priority to Chinese Patent Application 202010686770.1, titled “METHOD FOR RESOLVING DEFECT OF SURFACE STRUCTURE OF TRENCH AND METHOD FOR PREPARING SEMICONDUCTOR STRUCTURE”, filed on Jul. 16, 2020, which is incorporated herein by reference in its entirety.

### TECHNICAL FIELD

The present disclosure relates to the technical field of semiconductor preparation, and in particular to a method for resolving a defect of surface structures of trenches and a method for preparing a semiconductor structure.

### BACKGROUND

In the existing semiconductor preparing process, after etching, the by-products residue, for example, in the trenches of the word line (WL) structures, is removed by ashing (ASH). In this way, oxide particles will be generated, which will be adhered to the surfaces of the WL trenches. If the oxide particles are not completely removed, a large-particle defect will occur after tungsten deposition (W DEP).

When the above large particle defect is formed and these large particles are exactly above the WL trenches, they will block channel etching and cause WL W Under-ETCH in the subsequent etching process, which will cause bit line coupling and WL short (BLC-WL short). As a result, cross fail may occur in the final reliability test, resulting in low yield.

### SUMMARY

One aspect of the present disclosure provides a method for resolving a defect of surface structures of trenches. The method includes:

cleaning the trenches on a base with a cleaning liquid after the trenches are formed on the base, where the cleaning liquid is water.

According to the above technical solution, the method for resolving a defect of surface structures of trenches proposed by the present disclosure has the following advantages and positive effects:

This method cleans the trenches on the base with water as a cleaning liquid after the trenches are formed on the base. Through the above design, the present disclosure can effectively resolve the particle defect in the surface structures of the trenches of, for example, word line (WL) structures.

Another aspect of the present disclosure provides a method for preparing a semiconductor structure. The method includes:

preparing a base;

forming trenches on the base;

cleaning the trenches on the base with a cleaning liquid, where the cleaning liquid is water; and

ashing the base.

According to the above technical solution, the method for preparing a semiconductor structure proposed by the present disclosure has the following advantages and positive effects:

By adopting the above method for resolving a defect of surface structures of trenches, the method for preparing a semiconductor structure can optimize the tungsten (W) etching effect in the WL structures, and significantly solve the problem of cross fail in the WL structures.

### BRIEF DESCRIPTION OF THE DRAWINGS

FIG. 1 is a top view of an array in a step of a method for preparing a semiconductor structure according to the present disclosure.

FIG. 2 is a cross-sectional view taken along line A-A in FIG. 1.

FIG. 3 is a cross-sectional view in another step of the method for preparing a semiconductor structure according to the present disclosure.

FIG. 4 is a cross-sectional view in another step of the method for preparing a semiconductor structure according to the present disclosure.

FIG. 5 is a top view of an array in another step of the method for preparing a semiconductor structure according to the present disclosure.

FIG. 6 is a cross-sectional view taken along line D-D in FIG. 5.

FIG. 7 is a top view of an array in a step of an existing method for preparing a semiconductor structure.

FIG. 8 is a cross-sectional view taken along line E-E in FIG. 7.

### REFERENCE NUMERALS

111. active region;
112. trench isolation region;
113. mask layer;
114. photomask layer;
120. trench;
130. oxide particle;
140. word line (WL) structure;
210. base;
240. WL structure;
241. etching residue.

### DETAILED DESCRIPTION

The exemplary implementations are described thoroughly below with reference to the accompanying drawings. The exemplary implementations may be implemented in various forms, and may not be limited herein. On the contrary, these exemplary implementations are provided to make the present disclosure comprehensive and complete and to fully convey the concept manifested therein to those skilled in the art. The same reference numerals in the figures indicate the same or similar structures, and thus their detailed description will be omitted.

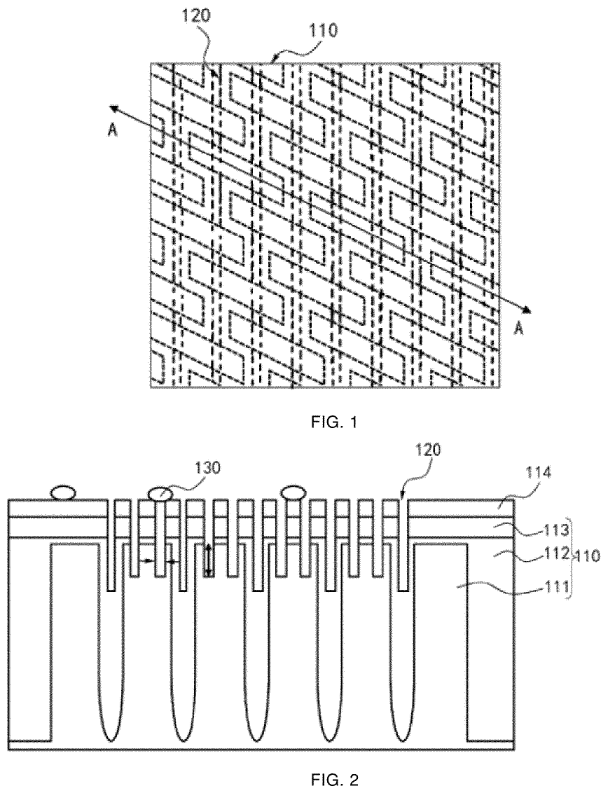

Referring to FIGS. 1 to 3, which representatively show the schematic diagrams of a semiconductor structure in the main steps of a method for resolving a defect of surface structures of trenches proposed by the present disclosure. In the exemplary implementation, the method for resolving a defect of surface structures of trenches proposed by the present disclosure is described by taking its application to a dynamic random access memory (DRAM) as an example. It is understandable for those skilled in the art that, in order to apply the relevant design of the present disclosure to the cleaning or other processes of other types of semiconductor devices, various modifications, additions, substitutions deletions or other changes may be made to the following specific implementations, but such changes are still within the scope of the principle of the method for resolving a defect of surface structures of trenches proposed by the present disclosure.

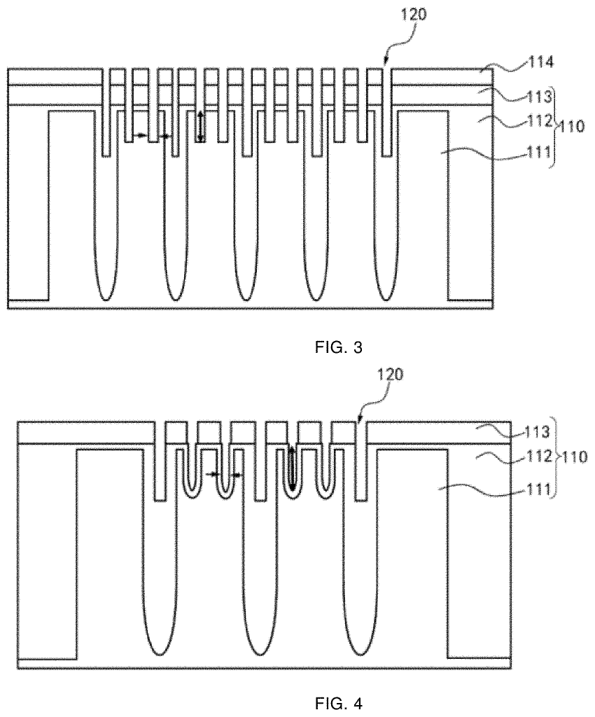

As shown in FIGS. 1 to 3, FIG. 1 specifically shows a top view of an array of trenches 120 formed on a base 110; FIG. 2 specifically shows a cross-sectional view taken along line A-A in FIG. 1, showing a cross-sectional structure of the trenches 120 to which oxide particles 130 are adhered; FIG. 3 specifically shows another cross-sectional view taken along line A-A in FIG. 1, showing a cross-sectional structure after the oxide particles 130 adhered to the trench 120 are removed through the method for resolving the defect of the surface structures of the trenches 120 proposed by the present disclosure. The processes and effects of various main steps of the method for resolving the defect of the surface structures of the trenches 120 proposed by the present disclosure are described in detail below in conjunction with the accompanying drawings.

As shown in FIGS. 1 to 3, the method for resolving the defect of the surface structures of the trenches 120 proposed by the present disclosure includes:

Clean the trenches 120 on the base 110 with a cleaning liquid after the trenches 120 are formed on the base 110, where the cleaning liquid is water.

In the method for resolving the defect of the surface structures of the trenches 120 proposed by the present disclosure, water is used as a cleaning liquid to clean the trenches 120 on the base 110. The process design can effectively resolve the particle defect in the surface structures of the trenches 120 of, for example, word line (WL) structures 140, thereby optimizing the subsequent tungsten (W) etching of the WL structures 140, without adversely influencing the WL structures 140. Compared with the existing semiconductor preparation method, it omits the step of cleaning the trenches on the base after etching, which will result in the residue of by-products such as oxide particles, leading to the generation of a large-particle defect after tungsten deposition (W DEP). The large particle will block channel etching and cause WL W Under-ETCH, which will cause bit line coupling and WL short (BLC-WL short). As a result, cross fail may occur in the final reliability test.

Preferably, in this implementation, the cleaning liquid may preferably be 50-70° C. water, such as 50° C., 55° C., 62° C. and 70° C. water. Since hot water is better for solution, it can better remove the by-products such as the oxide particles 130. In contrast, an acid/alkali cleaning liquid is used in the preparation process of other type of semiconductor. If the acid/alkali cleaning liquid is applied to the cleaning step involved in the present disclosure, it will corrode the WL structures and cause an electrical difference. The use of hot water as the cleaning liquid in the present disclosure can effectively avoid the problem. In other implementations, the cleaning liquid may also be water at other temperatures, that is, it may be less than 50° C. or may be greater than 70° C., such as 48° C. or 75° C., which is not limited herein.

Further, based on the process design that the cleaning liquid is water at 50-70° C., in this implementation, the cleaning liquid may be more preferably water at 60° C.

Preferably, in this implementation, the cleaning liquid may be deionized water.

Further, based on the process design of the temperature and type of the cleaning liquid, in this implementation, the cleaning liquid may be more preferably deionized water at 60° C.

Preferably, in this implementation, in the step of cleaning the base 110 with the cleaning liquid, the base 110 may be cleaned with the cleaning liquid multiple times.

Further, based on the process design of cleaning the base 110 multiple times with the cleaning liquid, in this implementation, the time and flow of each cleaning may be the same, such that each cleaning may achieve the same cleaning effect. The cleaning is repeated multiple times until the oxide particles 130 on the trenches 120 are completely removed or a predetermined removal effect is achieved. In other implementations, the time and flow of each cleaning may not be exactly the same. For example, the multiple cleanings may be carried out in an arithmetic sequence, or may be carried out in other ways. The multiple cleanings may be flexibly selected and adjusted according to different process needs, and is not limited herein.

For example, in another implementation, when the multiple cleanings are carried out in an arithmetic sequence, the cleaning time may be designed to decrease gradually until the oxide particles 130 are completely removed or a predetermined removal effect is achieved. In addition, in the above process, the cleaning flow may also be designed to decrease gradually. On this basis, the decreasing trend of the cleaning time and the decreasing trend of the cleaning flow may preferably be the same. In addition, when the multiple cleanings are carried out in an arithmetic sequence, the cleaning time may also be designed to increase gradually. In addition, the cleaning flow and the cleaning time may both decrease gradually or increase gradually, and the cleaning flow and the cleaning time may also be designed such that one increases gradually and the other decreases gradually, which is not limited herein.

For example, in another implementation, the time and flow of each cleaning may be designed according to process needs. For example, suppose a total of X (X≥3) cleanings are required, the time of first Y (1≤Y<X) cleanings and last Z (1≤Z<X, and Y+Z<X) cleanings may be designed to be less than the time of the remaining cleanings. Alternatively, the time of the first Y cleanings and the last Z cleanings may be greater than the time of the remaining cleanings. The cleaning flow may also be designed similarly, which will not be repeated here.

For example, in another implementation, when the time of the multiple cleanings is not exactly designed the same, the flow of a cleaning with a shorter time may be greater than or equal to that of a cleaning with a longer time, which is not limited herein

It should be noted here that the method for resolving the defect of the surface structures of the trenches 120 shown in the drawings and described in this specification only show a few examples of the many methods that may adopt the principles of the present disclosure. It should be clearly understood that the principle of the present disclosure is by no means limited to any details or any steps of the method for resolving the defect of the surface structures of the trenches 120 shown in the drawings or described in this specification.

In summary, in the method for resolving the defect of the surface structures of the trenches 120 proposed by the present disclosure, the trenches 120 on the base 110 are cleaned with water as a cleaning liquid after the trenches 120 are formed on the base 110. Through the above design, the present disclosure can effectively resolve the particle defect in the surface structures of the trenches 120 of, for example, a WL structures 140.

Based on the above detailed description of an exemplary implementation of the method for resolving the defect of the surface structures of the trenches 120 proposed by the present disclosure, an exemplary implementation of a method for preparing a semiconductor structure proposed by the present disclosure is described below.

Referring to FIGS. 1 to 6, which representatively show the schematic diagrams of a semiconductor structure in the main steps of the method for preparing a semiconductor structure proposed by the present disclosure. In the exemplary implementation, the method for preparing a semiconductor structure proposed by the present disclosure is described by taking its application to a DRAM as an example. It is understandable for those skilled in the art that, in order to apply the relevant design of the present disclosure to the preparation or other process of other type of semiconductor device, various modifications, additions, substitutions, deletions or other changes may be made to the following specific implementations, but such changes are still within the scope of the principle of the method for resolving a defect of surface structures of trenches 120 proposed by the present disclosure.

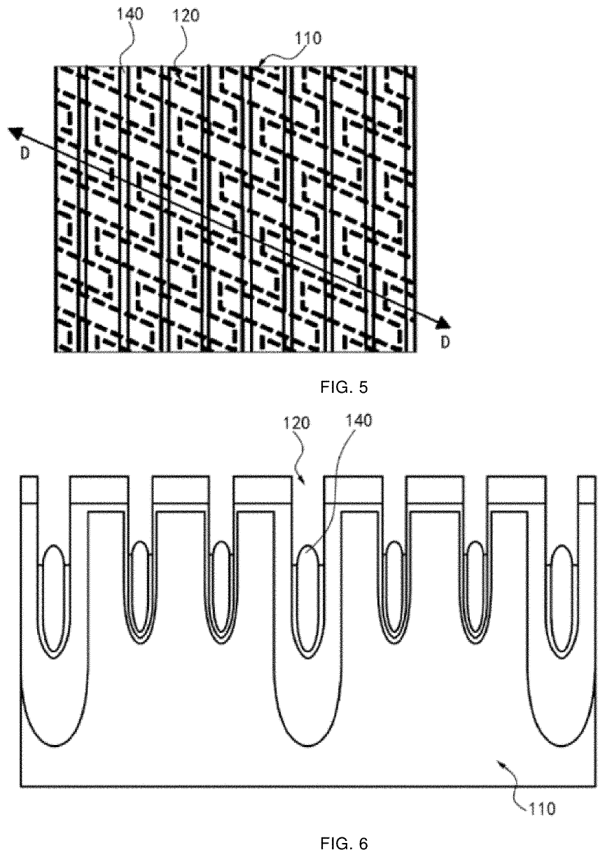

Referring to FIGS. 4 to 6, FIG. 4 specifically shows a cross-sectional view of the semiconductor structure after cleaning, ashing (ASH) and deposition of a silicon dioxide gate (DEP gate OX); FIG. 5 specifically shows a top view of an array of the semiconductor structure after W etching; FIG. 6 is a cross-sectional view taken along line D-D in FIG. 5. The processes and effects of various main steps of the method for preparing a semiconductor structure proposed by the present disclosure are described in detail below in conjunction with the accompanying drawings.

As shown in FIGS. 1 to 6, in this implementation, the method for preparing a semiconductor structure proposed by the present disclosure includes:

Prepare a base 110.

Form trenches 120 on the base 110.

Clean the trenches 120 on the base 110 with a cleaning liquid, where the cleaning liquid is water.

Perform ASH, DEP gate OX and W etching on the base 110.

By adopting the above process design, the method for preparing a semiconductor structure proposed by the present disclosure can optimize the W etching effect in the WL structures 140, and significantly solve the problem of cross fail in the WL structures. In contrast, an acid/alkali cleaning liquid is used in the preparation process of other type of semiconductor. If the acid/alkali cleaning liquid is applied to the cleaning step involved in the present disclosure, it will corrode the WL structures and cause an electrical difference. The present disclosure uses water, especially, for example, hot water at 50-70° C., as a cleaning liquid to clean the base 110 before ASH, which can prevent other by-product from being oxidized to generate an unnecessary impurity and cause silicon damage.

Preferably, as shown in FIGS. 1 to 6, in this implementation, the base 110 may preferably include a substrate and a mask layer 113. The substrate may be a silicon substrate, a germanium substrate or a silicon-germanium substrate. The substrate is defined as an active region 111 by a trench isolation region 112 which is filled with silicon dioxide (SiO₂). The mask layer 113 is formed above the trench isolation region 112 and is, for example, silicon nitride (SiN). The silicon dioxide and the silicon nitride may be regarded as a mask layer together. A photomask layer 114 is formed on the mask layer 113. On this basis, the ASH process carried out on the base 100 is used to remove the photomask layer.

Preferably, in this implementation, the cleaning liquid may be 50-70° C. water, such as 50° C., 55° C., 62° C. and 70° C. water. In other implementations, the cleaning liquid may also be water at other temperatures, that is, it may be less than 50° C. or may be greater than 70° C., such as 48° C. or 75° C., which is not limited herein.

Further, based on the process design that the cleaning liquid is water at 50-70° C., in this implementation, the cleaning liquid may be more preferably water at 60° C.

Preferably, in this implementation, the cleaning liquid may be deionized water.

Further, based on the process design of the temperature and type of the cleaning liquid, in this implementation, the cleaning liquid may be more preferably deionized water at 60° C.

Preferably, in this implementation, in the step of cleaning the base 110 with the cleaning liquid, the base 110 may be cleaned with the cleaning liquid multiple times.

Further, based on the process design of cleaning the base 110 multiple times with the cleaning liquid, in this implementation, the time and flow of each cleaning may be the same, such that each cleaning may achieve the same cleaning effect. The cleaning is repeated multiple times until the oxide particles 130 on the trenches 120 are completely removed or a predetermined removal effect is achieved.

It should be noted here that the method for preparing a semiconductor structure shown in the drawings and described in this specification only show a few examples of the many methods that may adopt the principles of the present disclosure. It should be clearly understood that the principle of the present disclosure is by no means limited to any details or any steps of the method for preparing a semiconductor structure shown in the drawings or described in this specification.

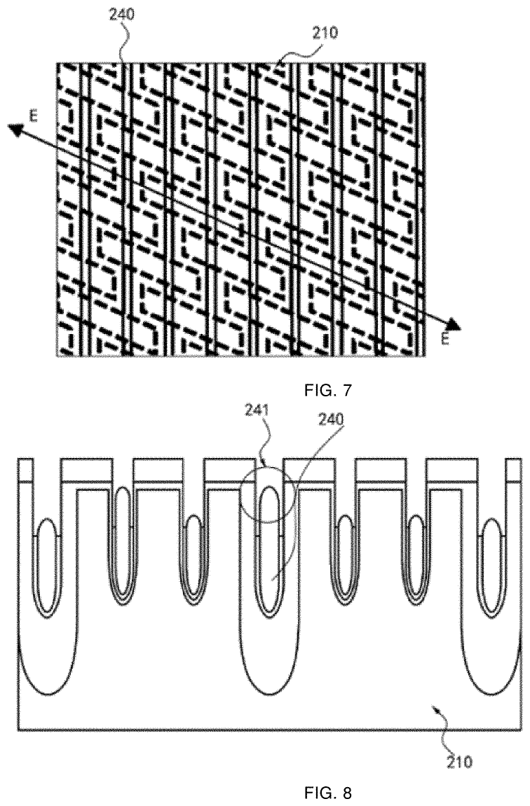

As shown in FIGS. 7 and 8, FIG. 7 specifically shows a top view of an array of a semiconductor structure after W etching in an existing method for preparing a semiconductor structure; FIG. 8 specifically shows a cross-sectional view taken along line E-E in FIG. 7. It can be seen that the existing semiconductor structure is limited by the traditional preparing method and the traditional cleaning method, which will lead to obvious WL W Under-ETCH, that is, an etching residue 241 occurs in the WL structures 240 in the trenches on the base. The method for preparing a semiconductor structure proposed by the present disclosure can greatly reduce the WL short of the semiconductor structure.

In summary, by adopting the above method for resolving a defect of surface structures of trenches, the method for preparing a semiconductor structure can optimize the W etching effect in the WL structures, and significantly solve the problem of cross fail in the WL structures. Compared with the prior art, the present disclosure can greatly reduce WL W Under-ETCH, thereby greatly reducing WL short and cross fail, so as to improve the final yield.

The present disclosure is described above with reference to several typical implementations. It should be understood that the terms used herein are intended for illustration, rather than limiting. The present disclosure may be specifically implemented in many forms without departing from the spirit or essence of the present disclosure.

Therefore, it should be understood that the above embodiments are not limited to any of the above details, but should be broadly interpreted according to the spirit and scope defined by the appended claims. Therefore, any changes and modifications falling within the claims or the equivalent scope thereof should be covered by the appended claims.

1. A method for resolving a defect of surface structures of trenches, comprising:
cleaning the trenches on a base with a cleaning liquid after the trenches are formed on the base, wherein the cleaning liquid is water.

2. The method for resolving the defect of the surface structures of the trenches according to claim 1, wherein the cleaning liquid is water at 50-70° C.

3. The method for resolving the defect of the surface structures of the trenches according to claim 2, wherein the cleaning liquid is water at 60° C.

4. The method for resolving the defect of the surface structures of the trenches according to claim 1, wherein the cleaning liquid is deionized water.

5. The method for resolving the defect of the surface structures of the trenches according to claim 1, wherein when the base is cleaned, the base is cleaned multiple times with the cleaning liquid.

6. The method for resolving the defect of the surface structures of the trenches according to claim 5, wherein a time of each cleaning is the same.

7. The method for resolving the defect of the surface structures of the trenches according to claim 5, wherein a flow of the cleaning liquid for each cleaning is the same.

8. The method for resolving the defect of the surface structures of the trenches according to claim 5, wherein a time of each cleaning increases or decreases in an arithmetic sequence.

9. The method for resolving the defect of the surface structures of the trenches according to claim 5, wherein a flow of the cleaning liquid for each cleaning increases or decreases in an arithmetic sequence.

10. The method for resolving the defect of the surface structures of the trenches according to claim 5, wherein a total of X cleanings are defined, wherein X≥3; a time of first Y cleanings and a time of last Z cleanings is less than a time of remaining cleanings, wherein 1≤Y<X, 1≤Z<X, and Y+Z<X.

11. The method for resolving the defect of the surface structures of the trenches according to claim 5, wherein a total of X cleanings are defined, wherein X≥3; a time of first Y cleanings and a time of last Z cleanings is greater than a time of remaining cleanings, wherein 1≤Y<X, 1≤Z<X, and Y+Z<X.

12. The method for resolving the defect of the surface structures of the trenches according to claim 5, wherein a time of multiple cleanings is not exactly the same; for any two cleanings, a flow of the cleaning liquid for a cleaning with a shorter time is greater than a flow of the cleaning liquid for a cleaning with a longer time.

13. A method for preparing a semiconductor structure, comprising:
preparing a base;
forming trenches on the base;
cleaning the trenches on the base with a cleaning liquid, wherein the cleaning liquid is water; and
ashing the base.

14. The method for preparing the semiconductor structure according to claim 13, wherein the cleaning liquid is water at 50-70° C.

15. The method for preparing the semiconductor structure according to claim 14, wherein the cleaning liquid is water at 60° C.

16. The method for preparing the semiconductor structure according to claim 13, wherein the cleaning liquid is deionized water.

17. The method for preparing the semiconductor structure according to claim 13, wherein when the base is cleaned, the base is cleaned multiple times with the cleaning liquid.

18. The method for preparing the semiconductor structure according to claim 17, wherein a time of each cleaning is the same.

19. The method for preparing the semiconductor structure according to claim 17, wherein a flow of the cleaning liquid for each cleaning is the same.

20. The method for preparing the semiconductor structure according to claim 17, wherein a time of each cleaning increases or decreases in an arithmetic sequence.
